(19) United States
(12) Patent Application Publication
(10) Pub. No.: US 2025/0159893 A1
(43) Pub. Date: May 15, 2025

(54) NON-VOLATILE MEMERY CELL AND METHOD OF FORMING THE SAME

(71) Applicant: TAIWAN SEMICONDUCTOR MANUFACTURING COMPANY, LTD., Hsinchu (TW)

(72) Inventor: Wen-Chao SHEN, Hsinchu (TW)

(21) Appl. No.: 18/506,142

(22) Filed: Nov. 10, 2023

(51) Int. Cl. H10B 43/30; G11C 16/04; G11C 16/10; G11C 16/14; H01L 29/66; H01L 29/78; H01L 29/792

(52) U.S. Cl. CPC H10B 43/30; G11C 16/0466; G11C 16/10; G11C 16/14; H10D 30/024; H10D 30/0413; H10D 30/6211; H10D 30/69; H10D 64/017

(57) ABSTRACT

Embodiments the present disclosure provide a MTP memory cell comprising two or more bits. The memory cell includes a FinFET transistor having two or more storage nodes formed around a channel region, and two or more gate electrodes formed over the two or more storage nodes. The memory cell may be implemented by either n-channel transistor or p-channel transistor.

### BACKGROUND

Many modern electronic devices contain electronic memory configured to store data. Electronic memory may be volatile memory or non-volatile memory (NVM). Volatile memory stores data while it is powered, while NVM is able to keep data when power is removed. Multi-time programmable (MTP) cells are one promising candidate for next generation NVM. NVMs are sometimes embedded in integrated circuits and are referred to as eNVM. Conventional eNVM use floating polycrystalline gate as charge storage node. While thin oxide and metal gate process during technology shrinking become the bottleneck of eNVM. Embodiments of the present disclosure provide a novel NVM cell suitable as eNVM.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E illustrate various views of a two-bit memory cell according to embodiments of the present disclosure.

FIG. 2A is a block diagram of the two-bit memory cell of FIGS. 1A-1C with a n-type channel region according to embodiments of the present disclosure.

FIG. 2B a schematic section view of the two-bit memory cell of FIG. 2A having a programmed bit and an erased bit.

FIG. 2C is a schematic circuit during an operation of reading a first bit of the two-bit memory cell shown in FIG. 2B.

FIG. 2D is a schematic circuit during an operation of reading a second bit of the two-bit memory cell shown in FIG. 2B.

FIG. 2E is a table showing reading results of the two-bit memory cell of FIG. 2B under various storage conditions.

FIG. 3A is a block diagram of the two-bit memory cell of FIGS. 1A-1C with a P-type channel region according to embodiments of the present disclosure.

FIG. 3B a schematic section view of the two-bit memory cell of FIG. 3A having a programmed bit and an erased bit.

FIG. 3C is a schematic circuit during an operation of reading a first bit of the two-bit memory cell shown in FIG. 3B.

FIG. 3D is a schematic circuit during an operation of reading a second bit of the two-bit memory cell shown in FIG. 3B.

FIG. 3E is a table showing reading results of the two-bit memory cell of FIG. 3B under various storage conditions.

FIGS. 4A-4B illustrates a table corresponding to operation conditions of the memory cell of FIGS. 1A-1C.

FIG. 5A is a layout view of a memory circuit according to embodiments of the present disclosure.

FIGS. 5B-5C are schematic partial sectional views of a memory cell in the memory circuit of FIG. 5A.

FIG. 6 is a layout view of a memory circuit according to embodiments of the present disclosure.

FIG. 7 is a flow chart of a method for forming a memory cell according to embodiments of the present disclosure.

FIGS. 8-10, 10A-10C, 11, 11A-11C, 12, 12A-12C, and 13A-13C illustrates various views of the forming a memory cell according to embodiment of the present disclosure.

FIG. 14 is a flow chart of a method for forming a memory cell according to embodiments of the present disclosure.

FIGS. 15, 15A-15C, 16, 16A-16C, and 17A-17C illustrates various views of the forming a memory cell according to embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the provide a MTP memory cell includes a Fin field effect transistor (FinFET) forming more one or more storage bits. In some embodiments, the MTP memory cell includes one source, one drain regions, a channel region connecting the source region and the drain region, two storage nodes formed over the channel region, and two control gates formed over two storage nodes respectively. In some embodiments, the storage gate comprises a silicon nitride gate electrode. The control gate includes a metal containing gate electrode. The channel region is a fin shaped region having a first side wall, a second sidewall, and a top surface connecting the first and second sidewalls. The storage notes are formed over the first and second sidewalls respectively. The control gates are formed over the storage gates. In some embodiments, the two storage nodes may include one storage electrode layer continuously formed over the first sidewall, the top surface, and the second sidewall of the fin region. The storage nodes and the control gated may be formed using a cut metal gate sequence in a process for fabricating complementary metal-oxide semiconductor (CMOS) transistors. The MTP memory cell according to the present disclosure may be formed from P-type FinFET or N-type FinFET.

The configuration of storage gate and metal control gate enables high density memory cell arrangement as well as high efficiency of programming and erase. Electrons may be selectively trapped in the storage nodes of the MTP memory cell so that the MTP memory cell may be selectively set in a programmed state or an erased state. For example, in the programmed state, electrons are trapped in the storage gate leading to a low read current. In the erased state, electrons are emptied out from the storage gate leading to a high read current. The MTP cell may be programmed or erased by applying a suitable control voltage to the control gate. The MTP cell may be programmed and/or erased by Fowler-Nordheim (FN) tunneling, CHE (channel hot electron injection), or BBHH (band-to-band hot hole injection). The storage nodes on opposing sides of a fin-shaped channel region may be read, charged, and erased independently using the corresponding control gates.

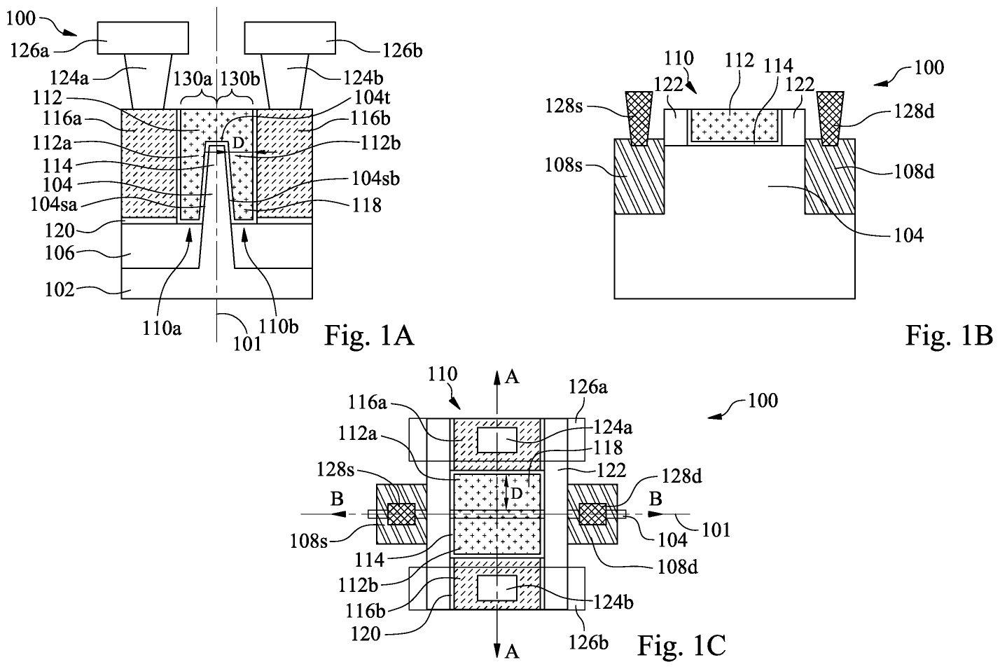

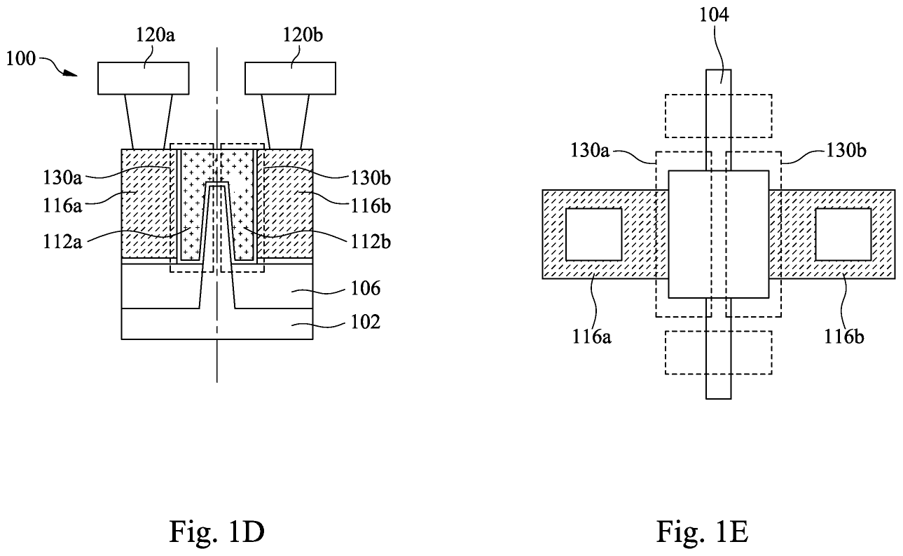

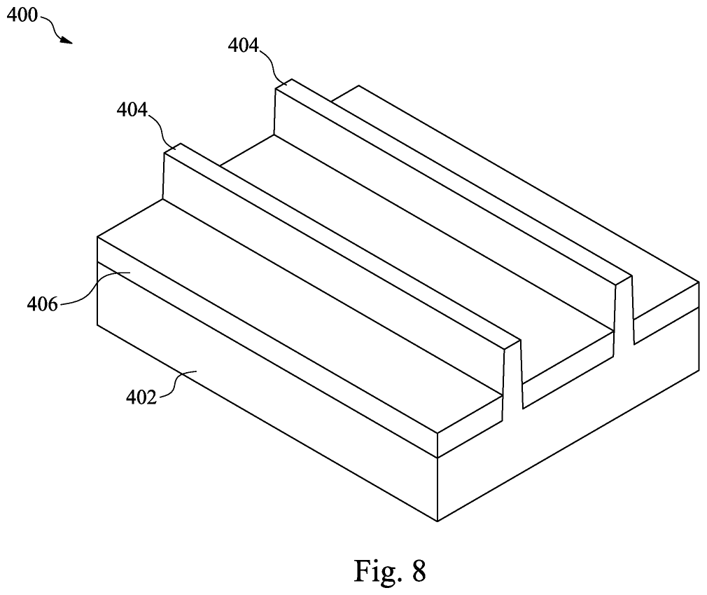

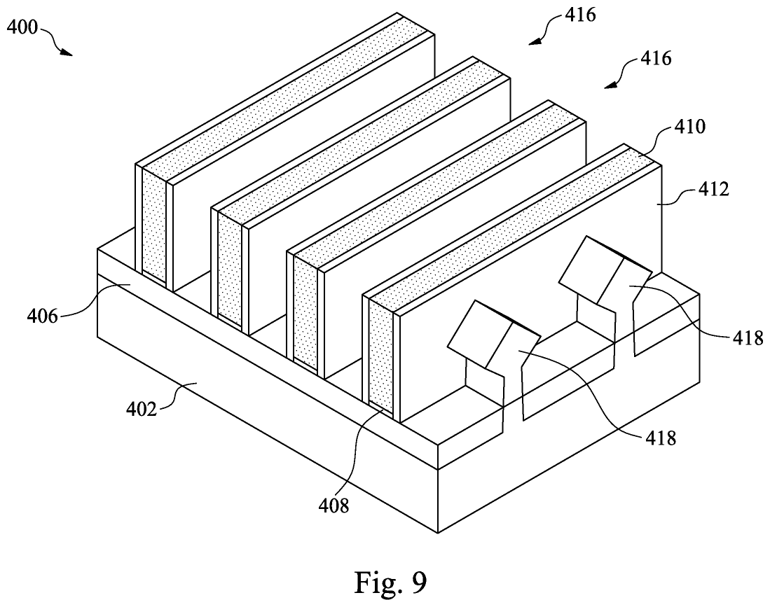

FIGS. 1A-1C illustrate various views of a two-bit memory cell 100 according to the present disclosure. FIG. 1C is a schematic top view of the two-bit memory cell 100. FIG. 1A is a schematic cross sectional view of the two-bit memory cell 100 along the A-A line in FIG. 1C. FIG. 8 is a schematic cross sectional view of the two-bit memory cell 100 along the B-B line in FIG. 1C. As shown in FIGS. 1A-1C, the two-bit memory cell 100 is a FinFET transistor formed on a semiconductor substrate 102. The two-bit memory cell 100 may include a fin shaped channel region 104. The fin shaped channel region 104 may be formed from the semiconductor substrate 102 and surrounded by an isolation region 106. The two-bit memory cell 100 includes a gate structure 110 extending along a direction substantially perpendicular to the fin shaped channel region 104. The gate structure 110 is formed over the fin shaped channel region 104 and the isolation region 106. A source region 108s and a drain region 108d are disposed on opposite sides of the gate structure 110. The source region 108s and the drain region 108d may be epitaxially grown from the fin shaped channel region 104.

In the gate structure 110, the fin shaped channel region 104 includes a first sidewall 104sa, a second sidewall 104sb, and a top surface 104t connecting the first sidewall 104sa and the second sidewall 104sb. The first sidewall 104sa and the second sidewall 104sb are facing opposite sides of the fin shaped channel region 104.

The gate structure 110 may include a first gate dielectric layer 114, a second gate dielectric layer 118, a third gate dielectric layer 120, a first gate electrode layer 112 and a second gate electrode layer 116 disposed between two sidewall spacers 122. The sidewall spacers 122 separates the source region 108s and the drain region 108d from the gate dielectric layers 114, 118, 120 and the gate electrode layers 112, 116. The first gate dielectric layer 114 is disposed over the fin shaped channel region 104 and portions of the sidewall spacers 122.

The first gate electrode layer 112 is disposed over the first gate dielectric layer 114 and surrounds the fin shaped channel region 104 between the sidewall spacers 122. In some embodiments, the first gate electrode layer 112 may be disposed substantially symmetrically about a central line 101 of the fin shaped channel region 104. A shown in FIG. 1A, the first gate electrode layer 112 are disposed on sidewalls 104s of the fin shaped channel region 104. In some embodiments, the first gate electrode layer 112 may extend to a distance D from both sides of the fin shaped channel region 104. As shown in FIG. 1A, the first gate electrode layer 112 includes a first portion 112a disposed over the first sidewall 104sa of the fin shaped channel region 104 and a second portion 112b disposed over the second sidewall 104sb of the fin shaped channel region 104. In some embodiments, the first portion 112a and the second portion 112b have substantially the same thickness D. The first portion 112a and the second portion 112b are connected over the top surface 104t of the fin shaped channel region 104.

The second gate electrode layer 116 is disposed outside the first gate electrode layer 112. In some embodiments, two portions of the second gate electrode layer 116a, 116b are disposed on the first and second portions 112a, 112b of the first gate electrode layer 112 respectively. The second gate dielectric layer 118 is disposed between the first gate electrode layer 112 and the second gate electrode layer 116. The third gate dielectric layer 120 is disposed between the second gate electrode layer 116 and the sidewall spacers 122 and between the second gate electrode layer 116 and the isolation region 106.

FIGS. 1D and 1E are simplified cross-sectional view and top view of the two-bit memory cell 100 to illustrate the two-bit structure. As shown in FIGS. 1D and 1E, the first portion 112a of the gate electrode layer 112 and the first gate dielectric layer 114 form a first storage node 130a while the second portion 112b of the gate electrode layer 112 and the first gate dielectric layer 114 form a second storage node 130b. In some embodiments, the first storage node 130a and the second storage node 130b each function as a storage for one bit forming the two-bit memory cell 100. The second electrode layer 116 adjacent the storage node 130a or 130b may be used as a control gate to program and erase the storage node 130a, 130b. Charge carriers, such as electrons, may be stored in or erased from the storage nodes 130a, 130b independently via by applying suitable voltages over the first portion 116a and second portions 116b of the second electrode layer 116.

By connecting the first portion 116a and the second portion 116b of the second electrode layer 116 through interconnect lines, appropriate control gate voltage may be applied to the storage nodes 130a, 130b to program and erase the two-bit memory cell 100. Efficiency of program and erase operations can be improved by selecting appropriate control gate voltages. Moreover, the distance D between the second gate electrode layer 116 and the channel region 104 may be selected to obtain desired cell coupling ratio. For example, decreasing the distance D may improve efficiency of program/erase operations. In some embodiments, the distance D is in a range between about 5 nm and about 100 nm. A distance D greater than 100 nm may not achieve effective program erase operation. A distance D less than 5 nm may not provide storage volume in the storage nodes 130a, 130b to trap sufficient electrons to induce a detectable difference between the programed state and the erased state.

Different combination of voltage may be applied to the first portion 116a and second portions 116b of second gate electrode layer 116, the source region 108s, and the drain region 108d to program (charge), erase, and read the charges in the storage nodes 130a, 130b. Gate contact features 124a, 124b are formed in contact with the first portion 116a and second portion 116b of the second gate electrode layers 116. In some embodiments, the gate contact features 124a, 124b are electrically connected to control lines 126a, 126b respectively. Control voltages may be applied to the first portion 116a and second portion 116b of the second gate electrode layer 116a via the control lines 126a, 126b respectively. A source contact feature 128s and a drain contact feature 128d are in contact with the source region 108s and the drain region 108d respectively. Voltages may be applied to the source region 108s and the drain region 108d via the source contact feature 128s and drain contact feature 128d respectively.

The semiconductor substrate 102 may be or comprise a bulk semiconductor substrate (e.g., a bulk silicon substrate), a silicon-on-insulator (SOI) substrate, or another suitable substrate material. In some embodiments, the semiconductor substrate 102 may include one or more doped region.

The fin shaped channel region 104 may be formed in a discrete doped region or a well region in the semiconductor substrate 102. The fin shaped channel region 104 may include p-type dopants or n-type dopants resulting in the two-bit memory cell 100 being a p-type FinFET or a n-type FinFET.

The source region 108s and the drain region 108d may include one or more layers of Si, SiP, SiC and SiCP for n-type device or Si, SiGe, Ge for p-type devices. For n-type devices, the source region 108s and the drain region 108d also include n-type dopants, such as phosphorus (P), arsenic (As), etc. For p-type devices, the source region 108s and the drain region 108d may include p-type dopants, such as boron (B).

The first gate electrode layer 112 may be formed from silicon nitride, silicon oxynitride, alloy of silicon oxide and silicon nitride, a combination thereof, or any suitable material for storing charges therein.

The first gate electrode layer 116 may be one or more layer of electrical conductive material, such as, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the first gate electrode layer 116 may include tungsten, aluminum, titanium nitride, tantalum nitride, or a combination thereof.

The first, second, and third gate dielectric layer 114, 118, 120 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the first, second, and third gate dielectric layer 114, 118, 120 may include SiOx, HfOx, and ZrOx, or a combination thereof. The first, second, and third gate dielectric layer 114, 118, 120 may have the same or different composition and/or thickness according to the circuit design.

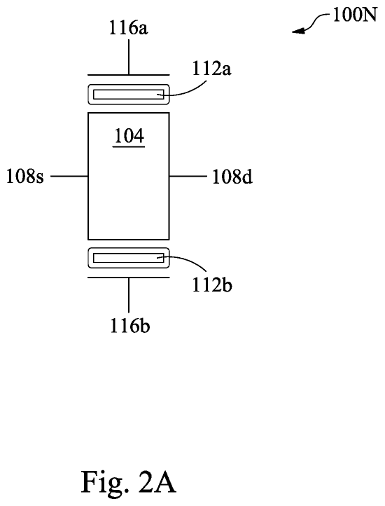

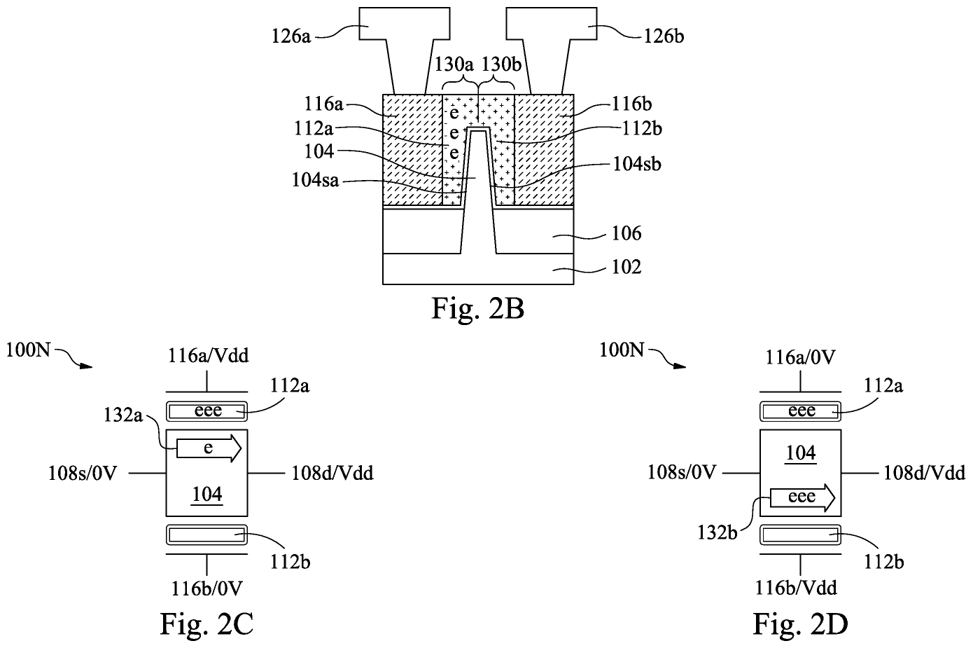

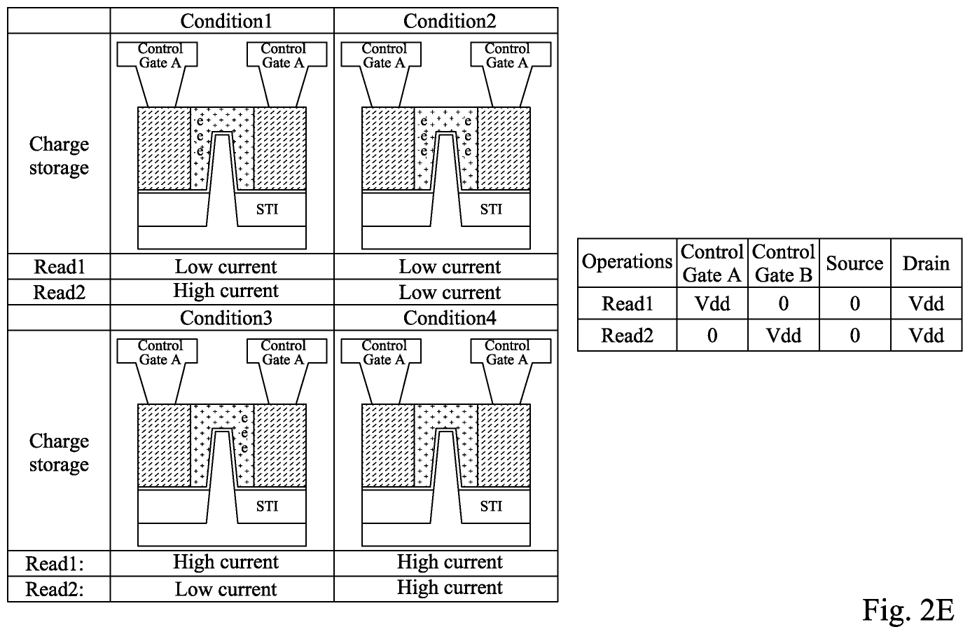

FIG. 2A illustrates a block diagram of a circuit of the two-bit memory cell 100 of FIGS. 1A-1C. FIG. 2B a schematic section view of the two-bit memory cell 100 of FIG. 2A having a programmed bit and an erased bit. FIG. 2C is a schematic circuit during an operation of reading a first bit of the two-bit memory cell 100 shown in FIG. 2B. FIG. 2D is a schematic circuit during an operation of reading a second bit of the two-bit memory cell 100 shown in FIG. 2B. FIG. 2E is a table showing reading results of the two-bit memory cell of FIG. 2B under various storage conditions.

As shown in FIG. 2A, the source region 108s, the drain region 108d, the channel region 104, and the gate structure 110 form a n-type field effect transistor 100N, in which majority of current carriers are electrons. In this case, the transistor 100N is a N-type FinFET. In some embodiments, the transistor 100N is a N-channel enhancement-type MOSFET. When the transistor 100N is turned ON, i.e., a sufficient positive voltage Vdd is applied to the drain region 108d and a sufficient positive voltage, e.g. Vdd, is applied to the first portion 116a and/or the second portion 116b of the second gate electrode layer 116, a current of electrons flows through the channel region 104. In some embodiments, the voltage Vdd indicates the positive power supply voltage of the MOSFET circuit. The voltage Vdd may be about 5V, about 3.3V, about 1.8V, about 1.2V, or any suitable value according to circuit design. In some embodiments, the first portion 116a and/or the second portion 116b of the second gate electrode layer 116 are controlled independently by signals from the control lines 126a, 126b respectively.

FIG. 2B shows the transistor 100N of the two-bit memory cell 100 with the storage node 130a in a programmed state and the storage node 130b in an initial state or an erased state.

For the storage node 130a, a portion of carrier electrons near the first sidewall 104sa of the fin shaped channel region 104 are trapped in the first portion 112a of the gate electrode layer 112. As shown in FIG. 2C, when the transistor 100N is turned ON by only applying a voltage via the first portion 116a of the second electrode layer 116, a current 132a flows through the channel region 104 along the first sidewall 104sa and the first storage node 130a. Because the first storage node 130a is under the programmed state which reduces carrier electrons along the first sidewall 104sa of the channel region 104, the current 132a is in a low current state.

For the storage node 130b, electrons are not trapped or pushed out from in the second portion 112b of the gate electrode layer 112. As shown in FIG. 2D, when the transistor 100N is turned ON by only applying a voltage via the second portion 116b of the second electrode layer 116, a current 132b flows through the channel region 104 along the second sidewall 104sb. Because the second storage node 130b under the initial or erased state which does not reduce carrier electrons along the second sidewall 104sb of the channel region 104, the current 132b is a normal or high current.

During a read operation, the transistor 100N is turned ON by applying suitable voltages to the first portion 116a and the second portion 116b of the second electrode layer 116, the values of the two bits in the two-bit memory cell 100 are obtained by the current 132a, 132b. A high current 132a, 132b through the channel region 104 indicates that the storage node 130a, 130b of the two-bit memory cell 100 is in an erased or initial state while a low current 132a, 132b through the channel region 104 indicates that the storage node 130a, 130b of the two-bit memory cell 100 is in programmed state.

FIG. 2E lists combinations of possible charge conditions in the storage nodes of the two-bit memory cell 100N of FIG. 2B and reading results under different reading conditions.

Alternatively, the source region 108s, the drain region 108d, the channel region 104, and the gate structure 110 may also a P-type transistor and function as a in the similar manner.

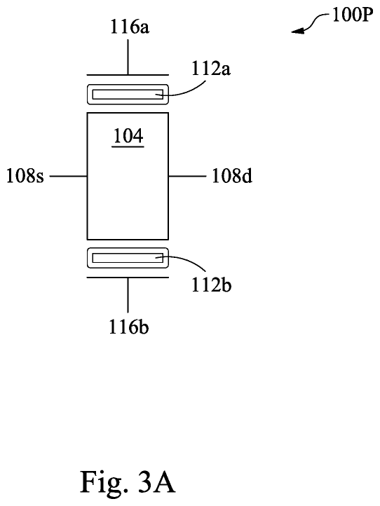

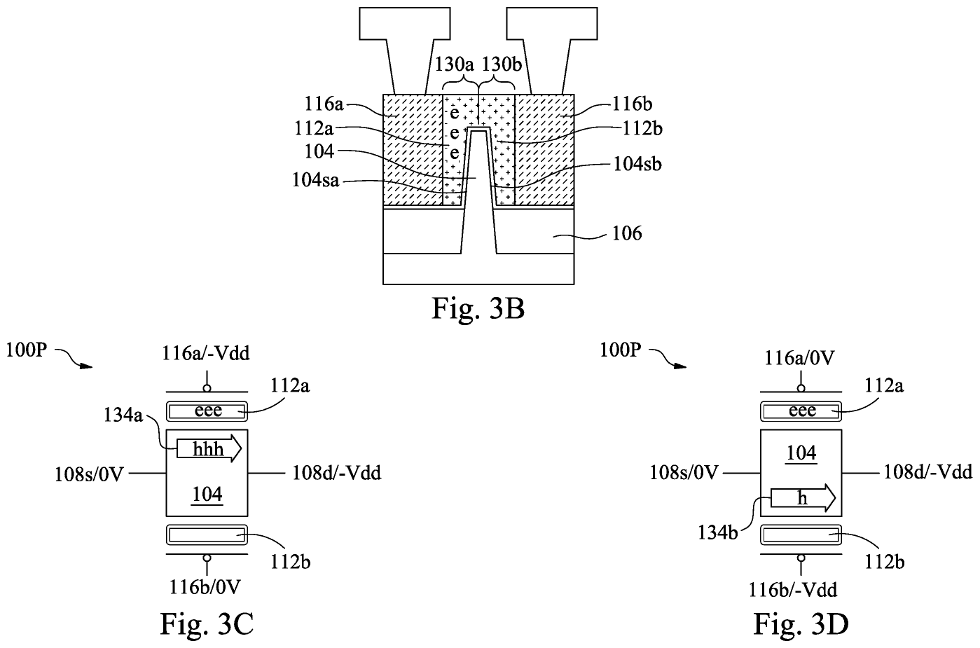

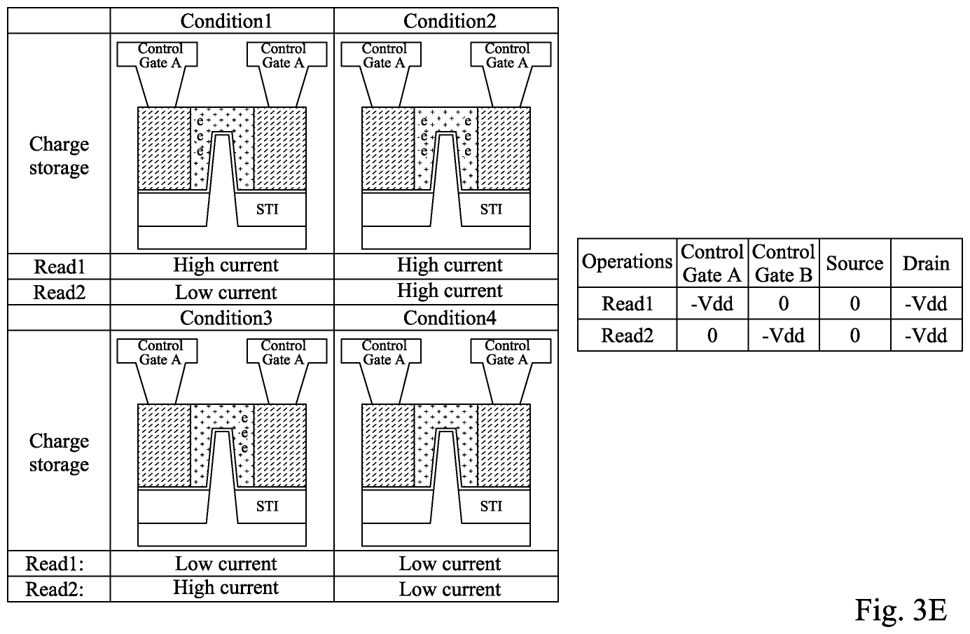

FIG. 3A illustrates a block diagram of a circuit of the two-bit memory cell 100 of FIGS. 1A-1C. In FIG. 3A, the source region 108s, the drain region 108d, the channel region 104, and the gate structure 110 form a p-type field effect transistor 100P, in which majority of current carriers are electrons. FIG. 3B a schematic section view of the two-bit memory cell 100P of FIG. 3A having a programmed bit and an erased bit. FIG. 3C is a schematic circuit during an operation of reading a first bit of the two-bit memory cell 100P shown in FIG. 3B. FIG. 3D is a schematic circuit during an operation of reading a second bit of the two-bit memory cell 100P shown in FIG. 3B. FIG. 3E is a table showing reading results of the two-bit memory cell of FIG. 3B under various storage conditions.

As shown in FIG. 3B, the transistor 100N is a P-type FinFET. In some embodiments, the transistor 100P is a P-channel enhancement-type MOSFET. When the transistor 100P is turned ON, i.e., by a sufficient negative voltage −Vdd is applied to the drain region 108d and a sufficient negative voltage, e.g. −Vdd, is applied to the first portion 116a and/or the second portion 116b of the second gate electrode layer 116, a current of electrons flows through the channel region 104. In some embodiments, the voltage −Vdd indicates the negative power supply voltage of the MOSFET circuit. The voltage −Vdd may be about −5V, about −3.3V, about −1.8V, about −1.2V, or any suitable value according to circuit design. In some embodiments, the first portion 116a and/or the second portion 116b of the second gate electrode layer 116 are controlled independently by signals from the control lines 126a, 126b respectively.

FIG. 3B shows the transistor 100P of the two-bit memory cell 100 with the storage node 130a in a programmed state and the storage node 130b in an initial state or an erased state.

For the storage node 130a, electrons are from the first sidewall 104sa of the fin shaped channel region 104 are driven to and trapped in the first portion 112a of the gate electrode layer 112. As a result, the carrier holes are increased along the first sidewall 104sa of the fin shaped channel region 104. As shown in FIG. 3C, when the transistor 100P is turned ON by only applying a voltage via the first portion 116a of the second electrode layer 116, a current 134a flows through the channel region 104 along the first sidewall 104sa and the first storage node 130a. Because the first storage node 130a is under the programmed state which results in increased carrier holes along the first sidewall 104sa of the channel region 104, the current 134a is in a high current state.

For the storage node 130b, electrons are not trapped or pushed out from in the second portion 112b of the gate electrode layer 112. Thus, the carrier holes along the second sidewall 104sb of the fin shaped channel region 104 are not affected. As shown in FIG. 3D, when the transistor 100P is turned ON by only applying a voltage via the second portion 116b of the second electrode layer 116, a current 134b flows through the channel region 104 along the second sidewall 104sb. Because the second storage node 130b under the initial or erased state which does not increase carrier holes along the second sidewall 104sb of the channel region 104, the current 132b is a normal or low current.

During a read operation, the transistor 100P is turned ON by applying suitable voltages to the first portion 116a and the second portion 116b of the second electrode layer 116, the values of the two bits in the two-bit memory cell 100 are obtained by the current 134a, 134b. A low current 134a, 134b through the channel region 104 indicates that the storage node 130a, 130b of the two-bit memory cell 100 is in an erased or initial state while a high current 134a, 134b through the channel region 104 indicates that the storage node 130a, 130b of the two-bit memory cell 100 is in programmed state.

FIG. 3E lists combinations of possible charge conditions in the storage nodes of the two-bit memory cell 100P of FIG. 3B, and reading results under different reading conditions.

As discussed above, the two-bit memory cell 100 is a multi-time programmable MTP cell with two states: a programed state and an erased state. Electrons are stored in the storage nodes 130a, 130b in programmed state and released from the storage nodes 130a, 130b in the erased state. The electrons stored in the storage nodes 130a, 130b affects the threshold voltages of the two-bit memory cell 100 and the current through the channel region 104. For the memory cell with a n-channel, the programed state has a low current and the erased state has a high current. For the memory cell with a p-channel, the programed state has a high current and the erased state has a low current.

By applying proper voltages on the source region 108s, the drain region 108d, and the first portion 116a and the second portion 116b of the second gate electrode layer 116 or the control gate, the storage nodes 130a, 130b of the two-bit memory cell 100 can be programed and erased. The two-bit memory cell 100 may be programmed by Fowler-Nordheim (FN) tunneling or by channel hot electron injection (CHE). The two-bit memory cell 100 may be erased by Fowler-Nordheim (FN) tunneling or by band-to-band hot hole injection (BBHH).

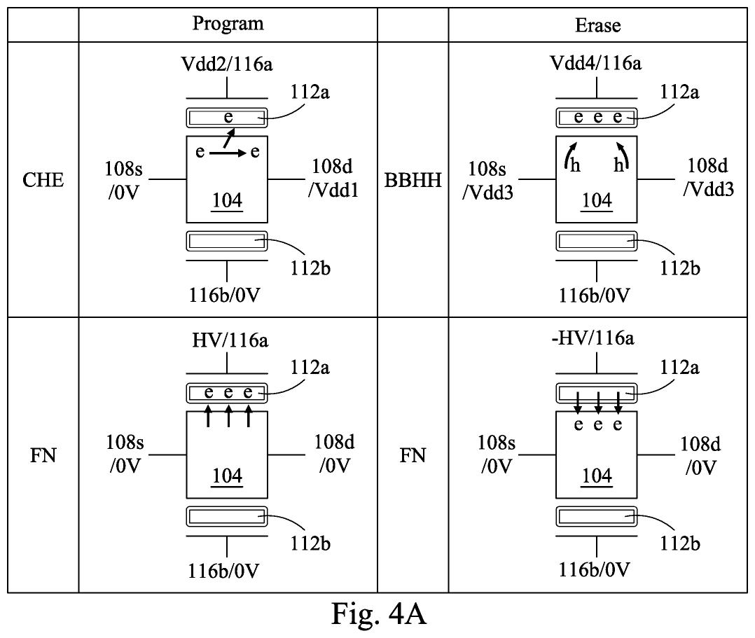

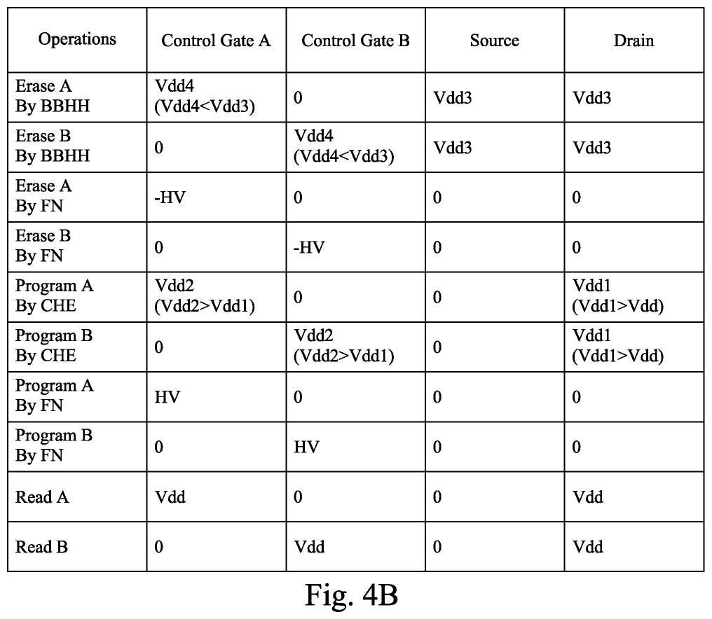

FIGS. 4A-4B illustrates a table corresponding to operation conditions of the memory cell of FIGS. 1A-1C. Particularly, FIG. 4A illustrates program and erase operations for the first storage node 130a of the two-bit memory cell 100 with a N-type FET 100N. The second storage node 130b may be programmed and erased by similar manner.

To program the storage node 130a of the memory cell with a N-type FET 100N using channel hot electron injection (CHE), a positive voltage Vdd2 is applied to the control gate or the first portion 116a of the second gate electrode layer 116, a positive voltage Vdd1 is applied to the drain region 108d while the voltage applied on the source region 108s and the second portion 116b of the second gate electrode layer 116 is about 0V. The FET 100N on the sidewall 104sa is turned on by the positive voltages Vdd2 and Vdd1, resulting in a current of electrons along the sidewall 104sa through the channel region 104. A portion of the electrons in the current may be injected into and trapped in the storage node 130a, turning the first storage node 130a of the two-bit memory cell 100 to the programmed state. In some embodiments, the positive voltages Vdd1 and Vdd2 are greater than Vdd. The voltages Vdd1 and Vdd2 may be selected according to circuit design. In some embodiments, the voltage Vdd2 is greater than the voltage Vdd1 to obtain increased charging speed.

To program the memory cell with a N-type FET 100N using Fowler-Nordheim (FN) tunneling, a positive high voltage HV is applied to the control gate or the first portion 116a of the second gate electrode layer 116 while voltages applied on the second portion 116b of the second gate electrode layer 116, the source region 108s and the drain region 108d are about 0V. When the positive high voltage HV is applied to the first portion 116a of the second gate electrode layer 116, electrons along the sidewall 104sa in the channel region 104 are “sucked” into and trapped in the storage node 130a, turning the storage node 130a of the two-bit memory cell 100 to the programmed state. In some embodiments, the high voltage HV may, for example, be within a range of about 7 to 10 V, within a range of about 11 to 18 V, within a range of about 7 to 18 V, or another suitable value.

To erase the memory cell with a N-type FET 100N using band-to-band hot hole injection (BBHH), a negative voltage Vdd4 is applied to the control gate or the first portion 116a of the second gate electrode layer 116 to attract holes injecting into the storage gate, a positive voltage Vdd3 is applied to the drain region 108d and to the source region 108s, and a 0V voltage is applied to the second portion 116b of the second gate electrode layer 116. The positive voltage Vdd4 is lower than the positive voltage Vdd3. The higher voltage Vdd3 in the source region 108s and the drain region 108d drives hot holes along the sidewall 104sa in the channel region 104 into the storage node 130 to erase the trapped electrons in the storage node 130a, thereby, turning the storage node 130a of the two-bit memory cell 100 to the erased state. In some embodiments, the positive voltages Vdd3 and Vdd4 are greater than Vdd.

To erase the memory cell with a N-type FET 100N using Fowler-Nordheim (FN) tunneling, a negative high voltage-HV is applied to the control gate or the first portion 116a of the second gate electrode layer 116 while voltages applied on the second portion 116b of the second gate electrode layer 116, the source region 108s and the drain region 108d are about 0V. When the negative high voltage-HV is applied to first portion 116a of the second gate electrode layer 116, electrons trapped in the storage node 130a are driven back into the channel region 104 via the sidewall 104sa, turning the first storage node 130a of the two-bit memory cell 100 to the erased state. In some embodiments, the negative high voltage-HV may, for example, be within a range of about −7 to −10 V, within a range of about −11 to −18 V, within a range of about −7 to −18 V, or another suitable value.

The program and erase methods may be mixed and combined according to circuit design. FIG. 4B is a table showing voltage conditions applied to the control gates or the first portion 116a and the second portion 116b of the second gate electrode layer 116, the source region 108s, and the drain regions for various operations.

Even though one fin shaped channel region 104 is shown in the two-bit memory cell 100. Memory cells according to the present disclose may include two or more fin structures to obtain greater channel region.

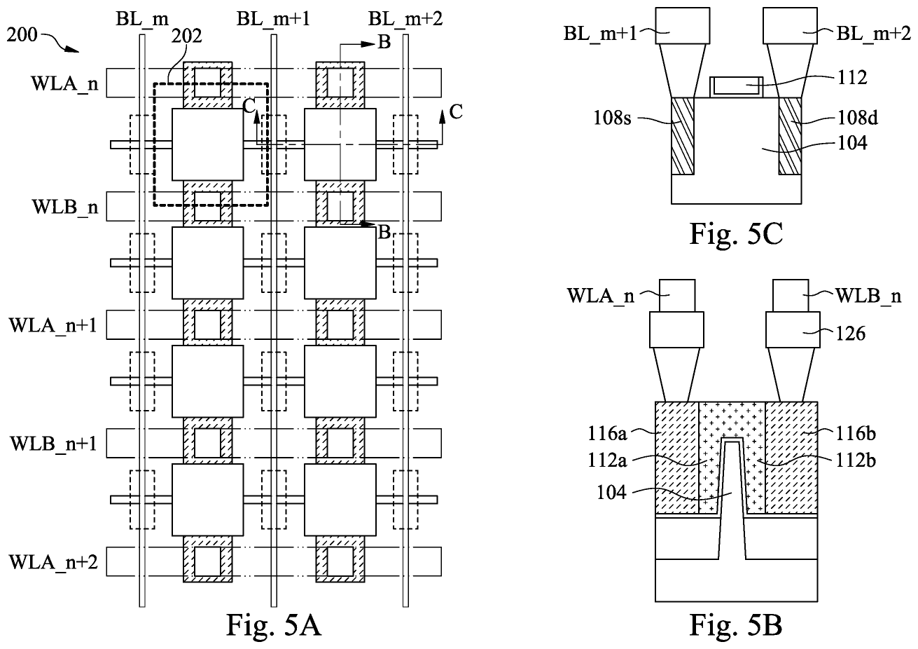

FIG. 5A is a layout view of a memory circuit 200 according to embodiments of the present disclosure. FIGS. 5B-5C are schematic partial sectional views of the memory circuit 200 along lines B-B and C-C of FIG. 5A respectively.

The memory circuit 200 comprises a plurality of rows and columns of memory cells 202. In some embodiments, each memory cells 202 may have a structure similar to the two-bit memory cell 100. In some embodiments, the memory cells 202 form an AND array. The memory circuit 200 includes a plurality of memory cells 202, a plurality of bit lines BL_m (m is an integer), a plurality of source lines SLm (m is an integer), a plurality of word lines WLAn and WLBn (n is an integer). Each memory cell 100 (memory cell 202) in the memory circuit 200 is connected to word lines WLAn and WLBn at the two portions 116a, 116b of the second electrode layer 116 so that the word lines WLAn and WLBn control operations to the two storage nodes 130a, 130b in the memory cell 100 independently. The memory cells 100 (memory cells 202) in the same row share the same word lines WLAn and WLBn. Each memory cell 100 (memory cell 202) in the memory circuit 200 is connected to two bit lines BLm and BLm+1 at the source region 108s and the drain regions 108d respectively. The source region 108s and drain regions 108d of the neighboring memory cells 100 (memory cells 202) in the same row may merge and share the same bit lines BLm.

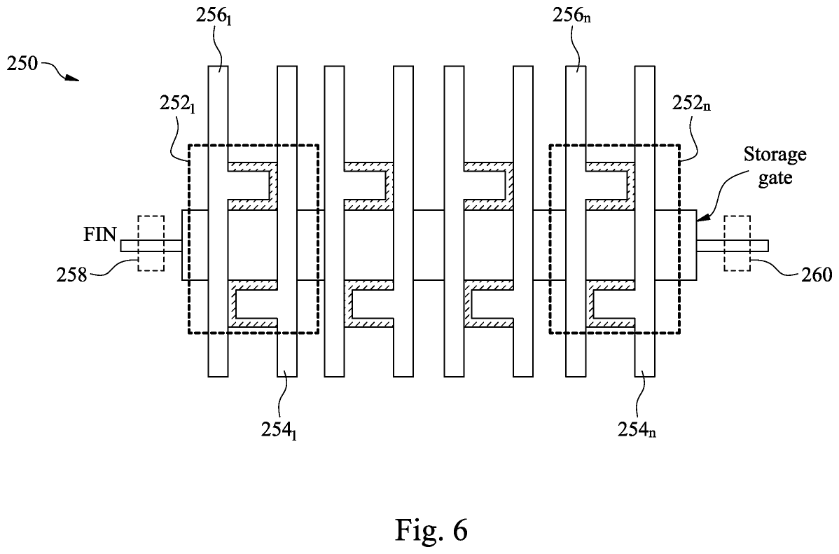

FIG. 6 is a layout view of a multi-bit MTP cell 250 according to embodiments of the present disclosure. The multi-bit MTP cell 250 may be used in place of the memory cell 100 except that multi-bit MTP cell 250 includes four or more bits. The multi-bit MTP cell 250 includes a cell chain having n memory cells 252₁, . . . 252ₙ formed in a row. In some embodiments, the memory cells 252₁, . . . 252ₙ may be similar to the two-bit memory cell 100 described above. Each of the memory cells 252₁, . . . 252ₙ may be a FinFET transistor with two storage nodes and two control gates 254₁, . . . 254ₙ and 256₁, . . . 256ₙ formed over the storage nodes. The memory cells 252₁, . . . 252ₙ may be fabricated from the same semiconductor fin or semiconductor fins. The memory cells 252₁, . . . 252ₙ share one pair of source region 258 and drain region 260. The number n is equal or greater than 2.

During operation, the control gates 254₁, . . . 254ₙ and 256₁, . . . 256ₙ may be connected to individual bit lines, and the source region 258 and drain region 260 are connected to two bit lines. Each bit in the multi-bit MTP cell 250 may be read, charged and erased by applying suitable voltages to the corresponding control gate 254₁, . . . 254ₙ, 256₁, . . . 256ₙ, the source region 258, and the drain region 260.

In some embodiments, the multi-bit MTP cell 250 may include bit line transistors disposed between the source region 258 and the first memory cell 252₁, and between the n^{th} memory cell 252ₙ and the drain region 260 respectively. The bit lines may be connected to drain of the bit line transistors.

A plurality of multi-bit MTP cells 250 may be arranged in an array in a memory circuit. The configuration of the multi-bit MTP cells 250 allows minimization of the two-bit memory cell 100, thus, thereby achieving high cell density.

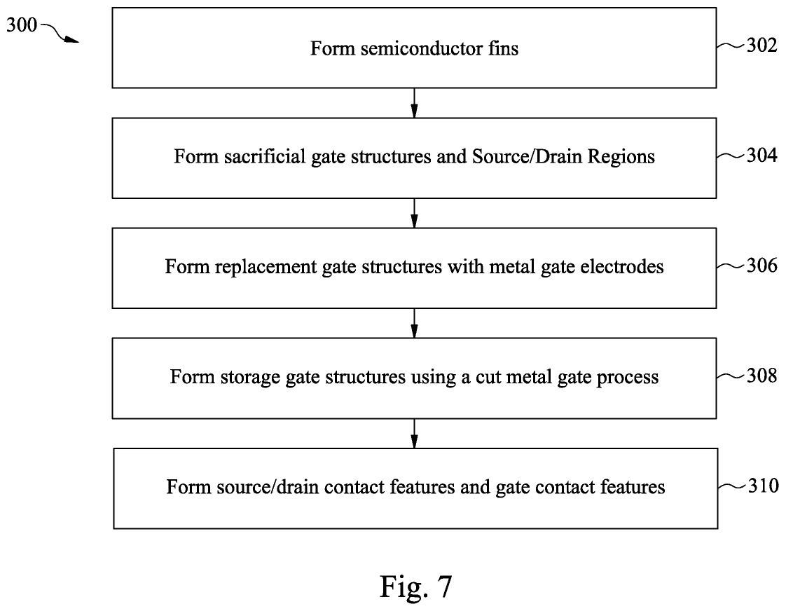

FIG. 7 is a flow chart of a method 300 for forming a memory circuit according to embodiments of the present disclosure. FIGS. 8-10, 10A-10C, 11, 11A-11C, 12, 12A-12C, and 13A-13C illustrate various views of the forming a memory circuit 400 according to embodiment of the present disclosure. The memory circuit 400 may include a plurality of memory cells, similar to the two-bit memory cell 100 discussed above.

At operation 302 of the method 300, semiconductor fins 404 are formed on a substrate 402, and an isolation layer 406 is formed in trenches between the semiconductor fins 404, as shown in 8. FIG. 8 is a schematic perspective view of the memory circuit 400 according to the present disclosure. The substrate 402 may include a single crystalline semiconductor material such as, but not limited to Si, Ge, SiGe, GaAs, InSb, GaP, GaSb, InAlAs, InGaAs, GaSbP, GaAsSb, and InP. The substrate 402 may include various doping configurations depending on circuit design. For example, the substrate 402 may one or more p-doped regions and one or more n-doped regions. The semiconductor fins 404 are then formed using one or more patterning and etching processes. The isolation layer 406 is formed in the trenches between the semiconductor fins 404 by a suitable deposition followed by an etch back process. The bottom profile of the isolation layer 406 is shown to be curved as an example. Depending on pitch and/or height of the semiconductor fins 404, a bottom profile of the isolation layer 406 may vary, for example curved, substantially flat, or other shapes. The isolation layer 406 may be formed by a high-density plasma chemical vapor deposition (HDP-CVD), a flowable CVD (FCVD), or other suitable deposition process. In some embodiments, the isolation layer 406 may include silicon oxide, silicon nitride, silicon oxynitride, fluorine-doped silicate glass (FSG), a low-k dielectric, combinations thereof. In some embodiments, the isolation layer 406 is formed to cover the semiconductor fins 404 by a suitable deposition process to fill the trenches between the semiconductor fins 404, a planarization process may be performed to expose the semiconductor fins 404, and then recess etched using a suitable anisotropic etching process to expose a portion of the semiconductor fins 404, as shown in FIG. 8.

At operation 304, sacrificial gate structures 416 and source/drain regions 418 are formed, as shown in FIG. 9. FIG. 9 is a schematic perspective view of the memory circuit 400 according to the present disclosure.

To form the sacrificial gate structures 416, a sacrificial gate dielectric layer 408 is conformally formed over the substrate 402. The sacrificial gate dielectric layer 408 is formed over the semiconductor fins 404 and the isolation layer 406. The sacrificial gate dielectric layer 408 may include silicon oxide, silicon nitride, a combination thereof, or the like. The sacrificial gate dielectric layer 408 may be deposited or thermally grown according to acceptable techniques, such as thermal CVD, CVD, ALD, and other suitable methods.

A sacrificial gate electrode layer 410 is deposited on the sacrificial gate dielectric layer 408 and then planarized, such as by a CMP process. The sacrificial gate electrode layer 410 includes silicon such as polycrystalline silicon, amorphous silicon, poly-crystalline silicon-germanium (poly-SiGe), or the like. In some embodiments, the sacrificial gate electrode layer 410 is subjected to a planarization operation. The sacrificial gate electrode layer 410 may be deposited using CVD, including LPCVD and PECVD, PVD, ALD, or other suitable process. A patterning operation is performed on the sacrificial gate electrode layer 410, and the sacrificial gate dielectric layer 408 to form the sacrificial gate structures 416 using one or more etching processes, such as one or more plasma etching processes or one or more wet etching processes. In some embodiments, a mask layer and a pad layer (not shown) are first patterned using a patterning process. The sacrificial gate electrode layer 410 is then patterned using the patterned mask layer and pad layer as an etching mask. In some embodiments, the sacrificial gate electrode layer 410 may be etched by an anisotropic etching, such as a reactive ion etching (RIE) process. The anisotropic etching has a greater etching rate along the Z direction than etching rates along the X and Y directions. During the etching of the sacrificial gate electrode layer 410, the sacrificial gate dielectric layer 408 on the semiconductor fins 404 may act as an etch stop to prevent the etchant from removing the semiconductor fins 404. In some embodiments, after patterning the sacrificial gate electrode layer 410, any exposed residual sacrificial gate dielectric layer 408 is removed by a suitable etch process. In some embodiments, the residual sacrificial gate dielectric layer 408 can be etched by tuning one or more parameters, such as etchant, etching temperature, etching solution concentration, etching pressure, source power, radio frequency (RF) bias voltage, etchant flow rate, of the etch process for etching the sacrificial gate electrode layer 410.

The sacrificial gate structures 416 cover a portion of the semiconductor fins 404. The portion of the semiconductor fins 404 covered by the sacrificial gate structures 416 eventually form a channel region. Gate sidewall spacers 412 are formed on sidewall of the sacrificial gate structures 416. The gate sidewall spacers 412 may have include one or more dielectric layers.

The semiconductor fins 404 not covered by the sacrificial gate structures 416 are recess etched to form source/drain recesses on both sides of the sacrificial gate structures 416. Epitaxial source/drain regions 418 are formed in the source/drain recess. In some embodiments, the epitaxial source/drain regions 418 may be grown in an epitaxial chamber by a suitable process.

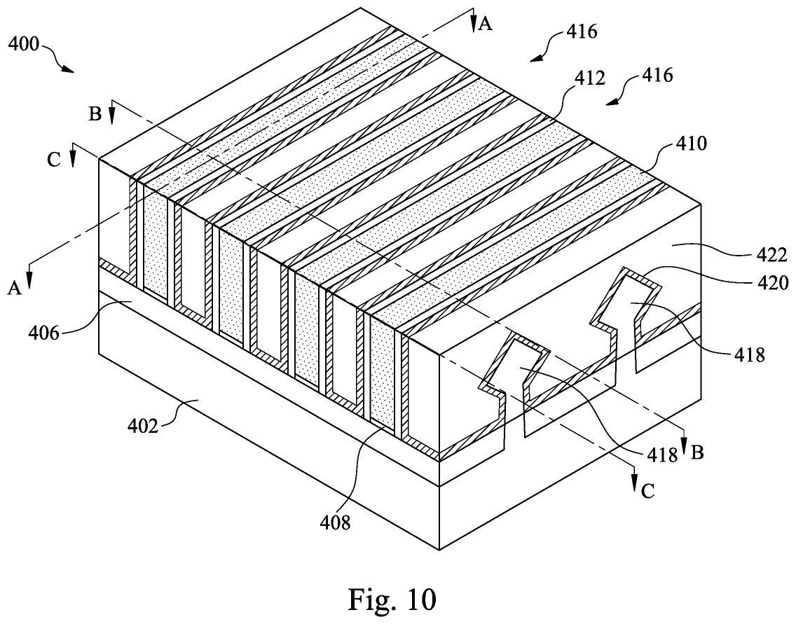

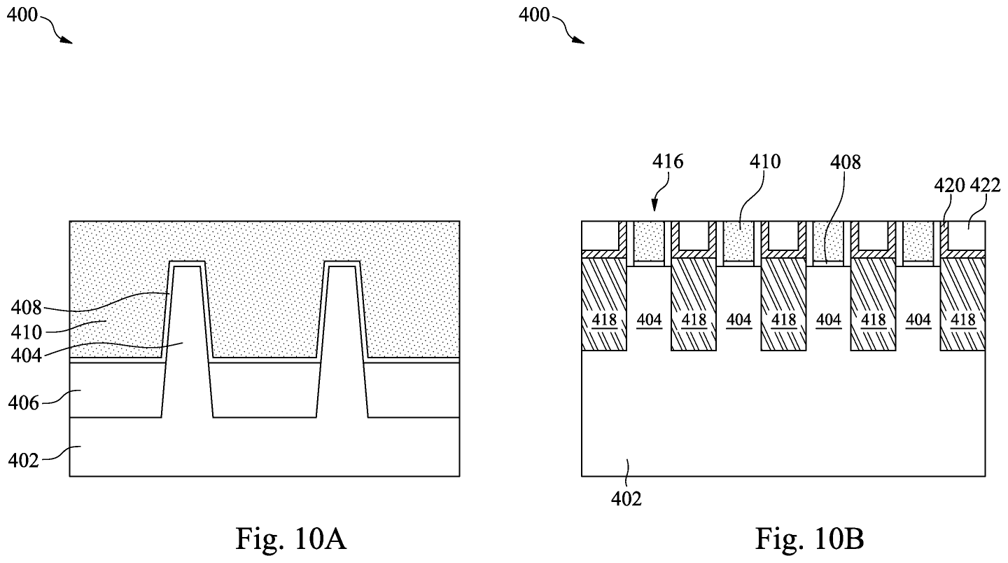

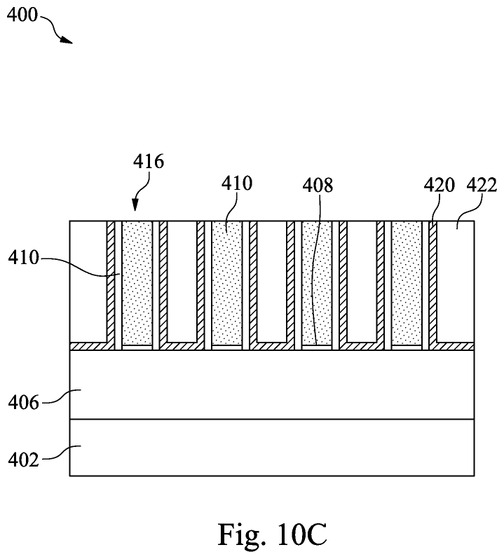

A contact etch stop layer (CESL) 420 and an interlayer dielectric (ILD) layer 422 are formed over the memory circuit 400, as shown in FIGS. 10, 10A, 10B, and 10C. FIG. 10 is a schematic perspective view of the memory circuit 400 according to the present disclosure. FIGS. 10A, 10B, and 10C are schematic sectional view of the memory circuit 400 along lines A-A, B-B, and C-C in FIG. 10 respectively.

The CESL 420 is conformally formed over exposed surfaces of the memory circuit 400. The CESL 420 is formed on the epitaxial source/drain regions 418, the gate sidewall spacers 412, and the isolation layer 406 if exposed. The CESL 420 may include SiN, SiON, SiCN or any other suitable material, and may be formed by CVD, PVD, or ALD. The interlayer dielectric (ILD) layer 422 is formed over the CESL 420. The materials for the ILD layer 422 include compounds comprising Si, O, C, and/or H, such as silicon oxide, SiCOH and SiOC. Organic materials, such as polymers, may be used for the ILD layer 422. In some embodiments, the ILD layer 422 may be formed by flowable CVD (FCV). The ILD layer 422 protects the epitaxial source/drain regions 418 during the removal of the sacrificial gate structures 416.

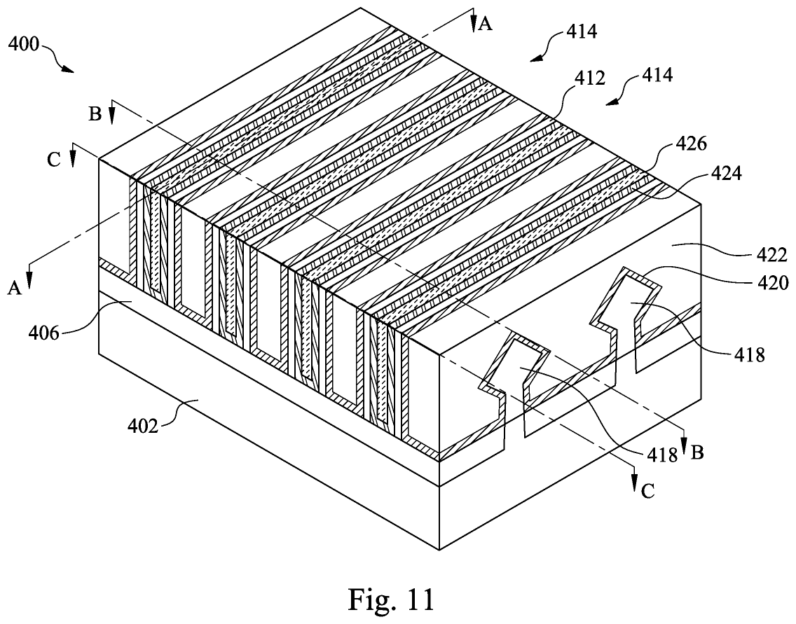

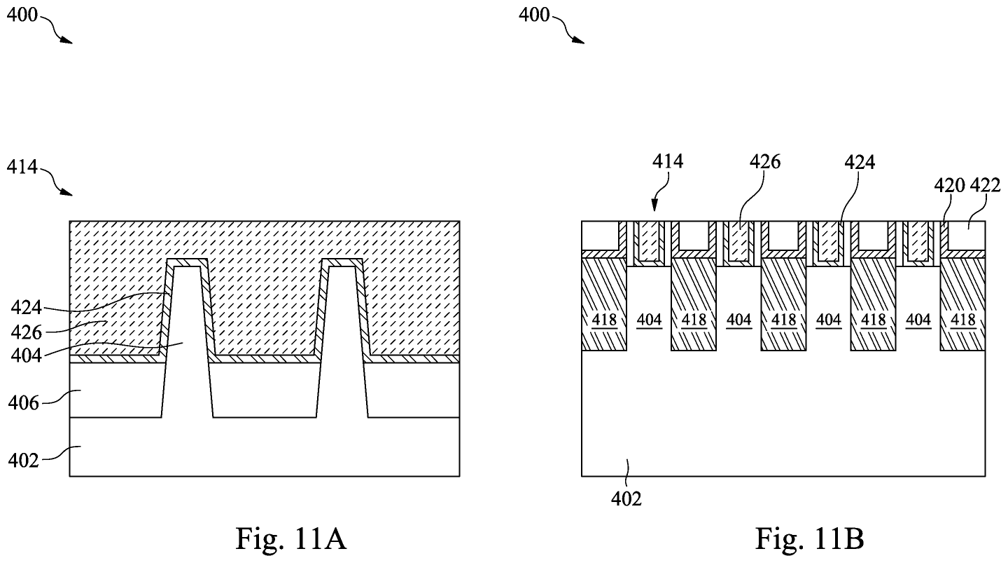

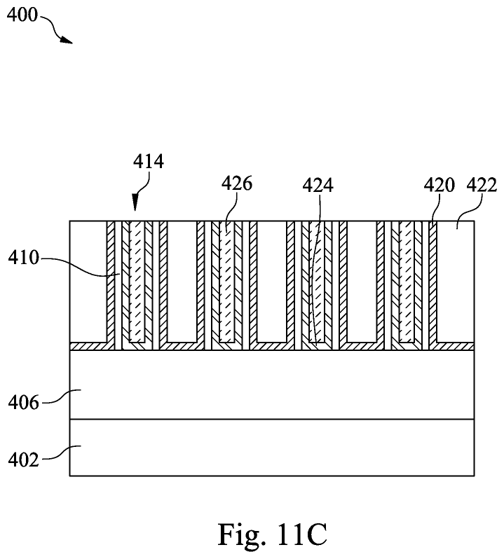

At operation 306, replacement gate structures 414 are formed as shown in FIGS. 11, 11A, 11B, and 11C. FIG. 11 is a schematic perspective view of the memory circuit 400 according to the present disclosure. FIGS. 11A, 11B, and 11C are schematic sectional view of the memory circuit 400 along lines A-A, B-B, and C-C in FIG. 11 respectively.

The sacrificial gate dielectric layer 408 and sacrificial gate electrode layer 410 are removed by one or more suitable process, such as dry etch, wet etch, or a combination thereof, to expose the semiconductor fins 404. In some embodiments, a wet etchant such as a tetramethylammonium hydroxide (TMAH) solution is used. The replacement gate structure may include a first gate dielectric layer 424, and a gate electrode layer 426.

The first gate dielectric layer 424 may be conformally deposited on exposed surfaces in the gate cavities. The first gate dielectric layer 424 may have different composition and dimensions for N-type devices and P-type devices and are formed separately using patterned mask layers and different deposition recipes. The first gate dielectric layer 424 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The first gate dielectric layer 424 may be formed by CVD, ALD or any suitable method.

The gate electrode layer 426 is then formed on the first gate dielectric layer 424 to fill the gate cavities. The gate electrode layer 426 may include one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 426 may be formed by CVD, ALD, electro-plating, or other suitable method. After the formation of the gate electrode layer 426, a planarization process, such as a CMP process, is performed to remove excess deposition of the gate electrode material and expose the top surface of the ILD layer 422.

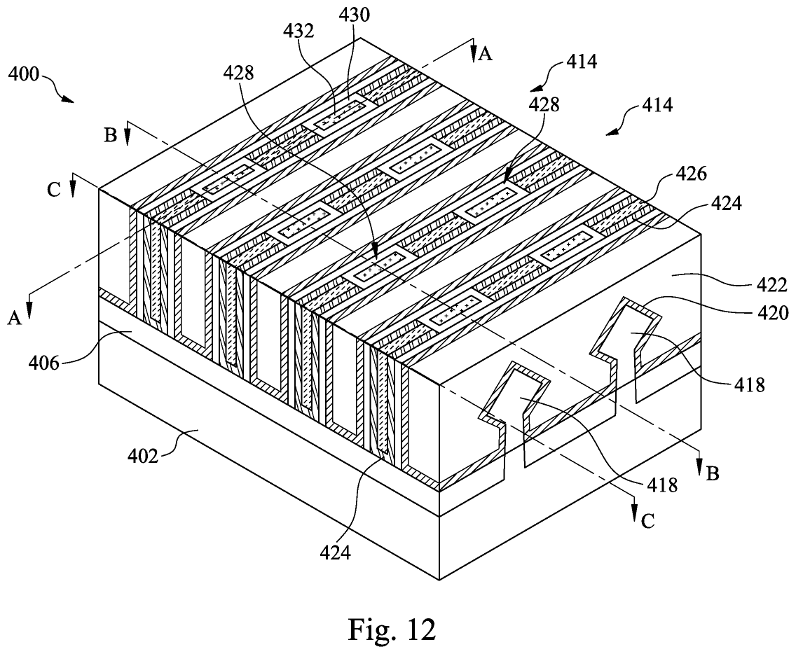

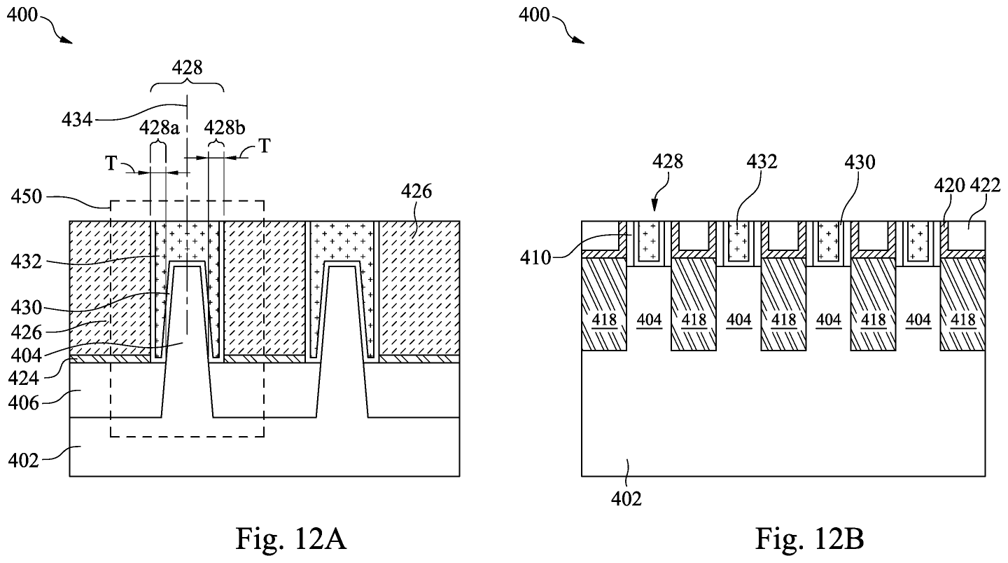

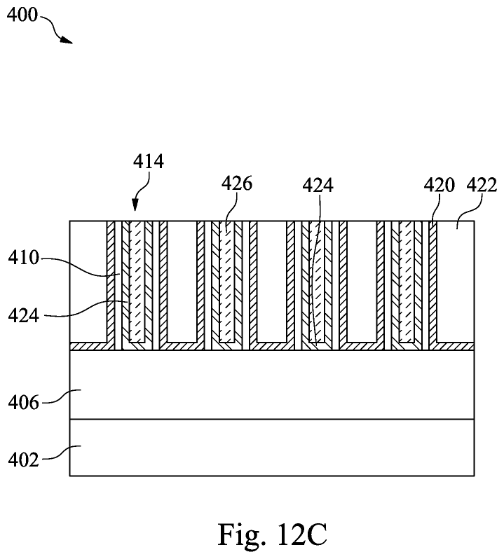

At operation 308, storage nodes 428a, 428b (collectively 428) are formed over the semiconductor fins 404 between the sidewall spacers 412, as shown in FIGS. 12, 12A, 12B, 12C. FIG. 12 is a schematic perspective view of the memory circuit 400 according to the present disclosure. FIGS. 12A, 12B, and 12C are schematic sectional view of the memory circuit 400 along lines A-A, B-B, and C-C in FIG. 12 respectively.

The storage nodes 428a, 428b are formed within the replacement gate structures 414 and over the semiconductor fins 404. A patterning process may be performed to “cut” the replacement gate structures 414 into sections by removing the gate electrode layer 426 and the first gate dielectric layer 424 over the semiconductor fins 404. After the cutting process, the semiconductor fins 404 are exposed between the sidewall spacers 412. A second gate dielectric layer 430 is then deposited over the exposed surfaces including the semiconductor fins 404, the isolation layer 406, the sidewall spacers 412, the first gate dielectric layer 424, and the gate electrode layer 426. A storage gate electrode layer 432 is then deposited over the second gate dielectric layer 430 and fills the openings over the semiconductor fins 404. The storage gate electrode layer 432 and the second gate dielectric layer 430 form the storage nodes 428.

In some embodiments, the second gate dielectric layer 430 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the second gate dielectric layer 430 may include SiOx, HfOx, and ZrOx, or a combination thereof. The second gate dielectric layer 430 may be selected may be formed by CVD, ALD or any suitable method. The composition and dimension of the second gate dielectric layer 430 may be selected according to circuit design.

In some embodiments, the storage gate electrode layer 432 may include one or more layers of material suitable for trapping electrons therein. In some embodiments, the storage gate electrode layer 432 be formed from silicon nitride, silicon oxynitride, alloy of silicon oxide and silicon nitride, a combination thereof, or any suitable material for storing charges therein. The storage gate electrode layer 432 may be formed by CVD, ALD or any suitable method. After deposition of the storage gate electrode layer 432, a planarization process, such as CMP, may be performed to expose the gate electrode layer 426 for subsequent formation of gate contact features.

In some embodiments, the storage nodes 428 may be formed substantially symmetrical about a central axis 434 of the corresponding semiconductor fin 404. As shown in FIG. 12A, the storage gate electrode layer 432 may have substantially equal thickness T on either side of the semiconductor fin 404. The thickness T may be in a range between about 5 nm and about 100 nm. In some embodiments, the second gate dielectric layer 430 may have a thickness in a range between about 2 nm and about 10 nm. In some embodiments, a ratio of the thickness of the second gate dielectric layer 430 over the storage gate electrode layer 432 may be in a range between about 0.01 and about 0.2.

As shown in FIG. 12A, the second gate dielectric layer 430 is disposed between the gate electrode layer 426 and the storage gate electrode layer 432. In some embodiments, the first gate dielectric layer 424 and the second gate dielectric layer 430 may be formed from the same material. In other embodiments, the first gate dielectric layer 424 and the second gate dielectric layer 430 may be formed different material according to circuit design.

After operation 308, a plurality of memory cells 450 are formed over the substrate 402. The memory cells 450 are similar to the two-bit memory cell 100 of FIGS. 1A-1C.

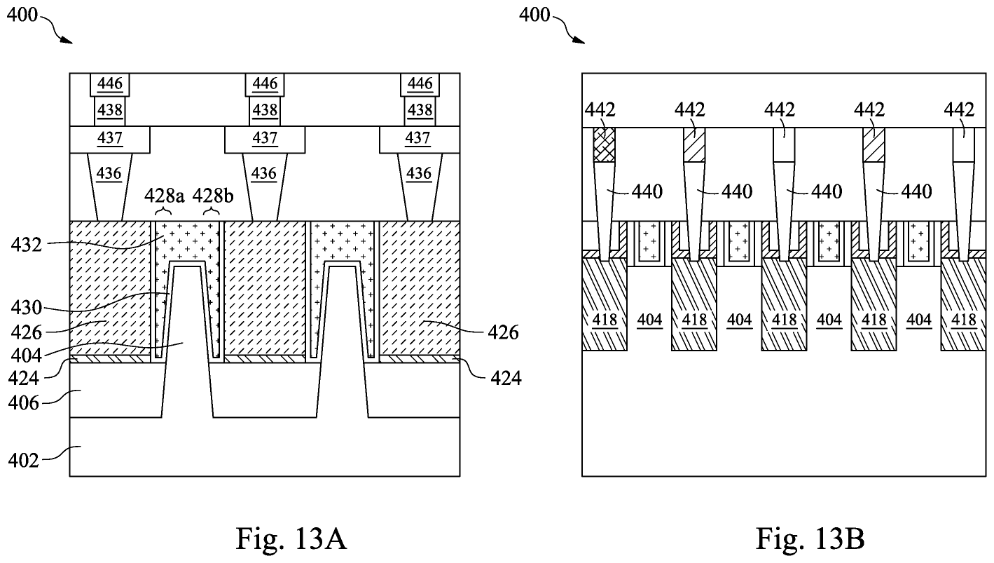

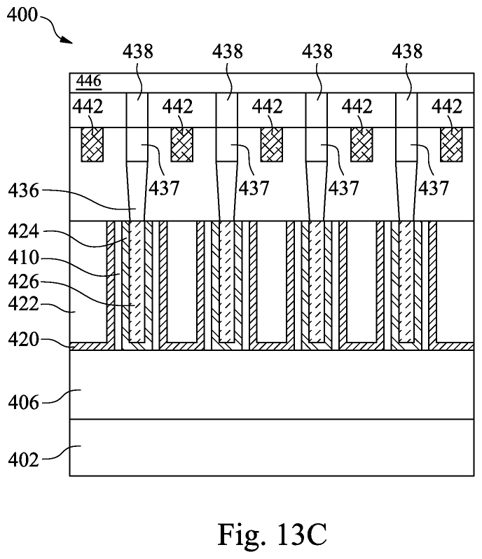

At operation 310, gate contact features 436 and/or source/drain contact features 440 may be formed to connect the memory cells 450, as shown in FIGS. 13A, 13B, 13C. FIGS. 13A, 13B, and 13C are schematic sectional view of the memory circuit 400 along lines A-A, B-B, and C-C in FIG. 12 respectively.

In operation 310, conductive lines and vias are formed in dielectric materials in layers to provide electrical connection to the source/drain regions 418 and the gate electrode layer 426 so that the memory cells 450 may be read, programmed, and erased. In some embodiments, the gate contact features 436 are formed to connect the gate electrode layer 426 to word lines 446 through contact lines 437 and contact vias 438. The source/drain contact features 440 are formed to connect the source/drain regions 418 to bit lines 442. In some embodiments, the bit lines 442 are disposed in a first IMD layer and extend along the y-axis, while the word lines 446 are disposed in a second IMD layer and extend along the x-axis. The conductive lines and vias may be arranged in different configurations according to circuit design.

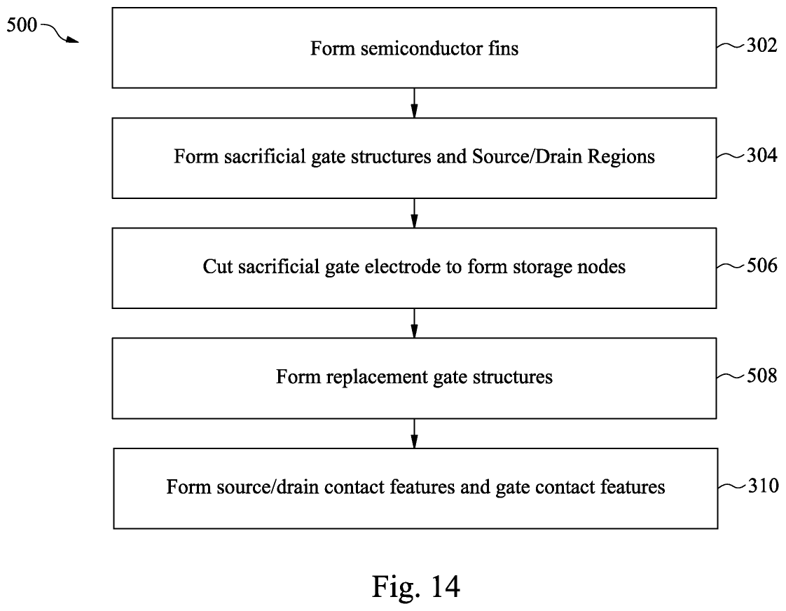

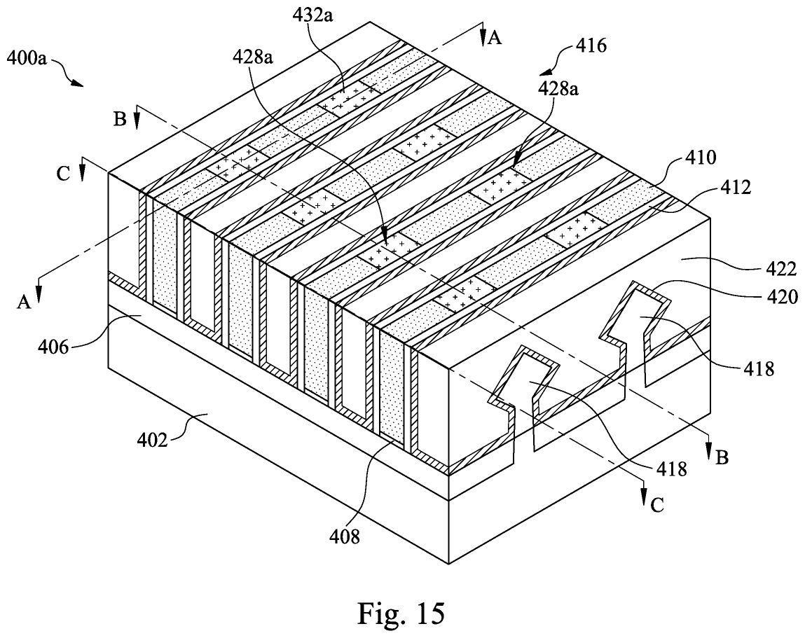

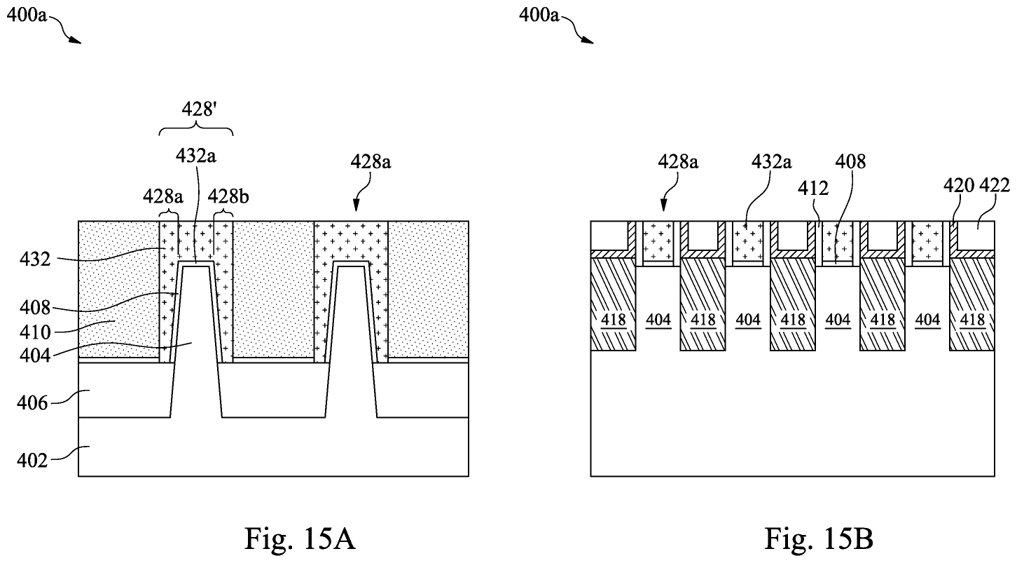

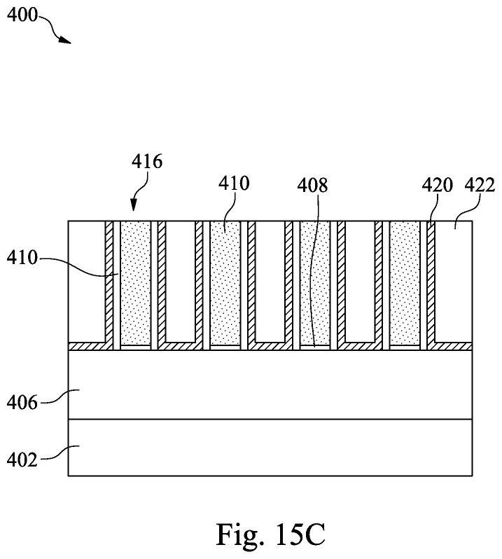

FIG. 14 is a flow chart of a method 500 for forming a memory circuit according to embodiments of the present disclosure. FIGS. 15, 15A-15C, 16, 16A-16C, and 17A-17C illustrates various views of the forming a memory circuit 400a according to embodiment of the present disclosure. The memory circuit 400a may include a plurality of memory cells, similar to the two-bit memory cell 100 discussed above. The method 500 starts with operation 302 and 304 as discussed above and shown in FIGS. 8-10.

In operation 506, storage nodes 428′ by cutting sacrificial gate electrode 410 over the semiconductor fins 404 and depositing a storage gate electrode layer 432a, as shown in FIGS. 15, 15A, 15B, 15C. FIG. 15 is a schematic perspective view of the memory circuit 400a according to the present disclosure. FIGS. 15A, 15B, and 15C are schematic sectional view of the memory circuit 400a along lines A-A, B-B, and C-C in FIG. 15 respectively.

The storage nodes 428′ are formed within the sacrificial gate structures 416 and over the semiconductor fins 404. A patterning process may be performed to “cut” the sacrificial gate electrode layer 410 into sections by patterning and etching process. After the cutting process, the sacrificial gate dielectric layer 408 is exposed between the sidewall spacers 412. The storage gate electrode layer 432a is then deposited over the sacrificial gate dielectric layer 408 and fills the openings between the sidewall spacers 412. The storage gate electrode layer 432a and the sacrificial gate dielectric layer 408 form the storage nodes 428′. The storage gate electrode layer 432a is in contact with the sidewall spacers 412 and the sections of the sacrificial gate electrode layer 410.

In some embodiments, the storage gate electrode layer 432a may include one or more layers of material suitable for trapping electrons therein. In some embodiments, the storage gate electrode layer 432a be formed from silicon nitride, silicon oxynitride, alloy of silicon oxide and silicon nitride, a combination thereof, or any suitable material for storing charges therein. The storage gate electrode layer 432a may be formed by CVD, ALD or any suitable method. After deposition of the storage gate electrode layer 432a, a planarization process, such as CMP, may be performed to expose the sacrificial gate electrode layer 410 for replacement gate process.

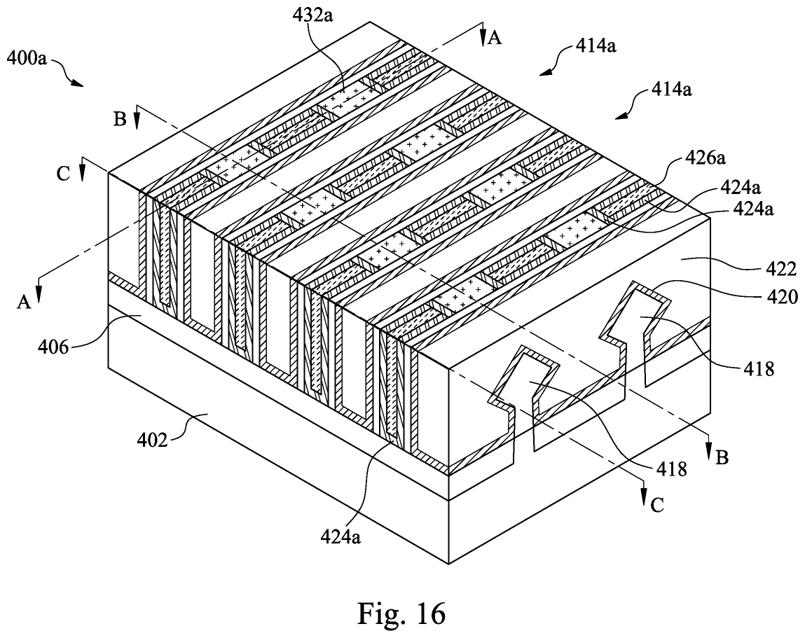

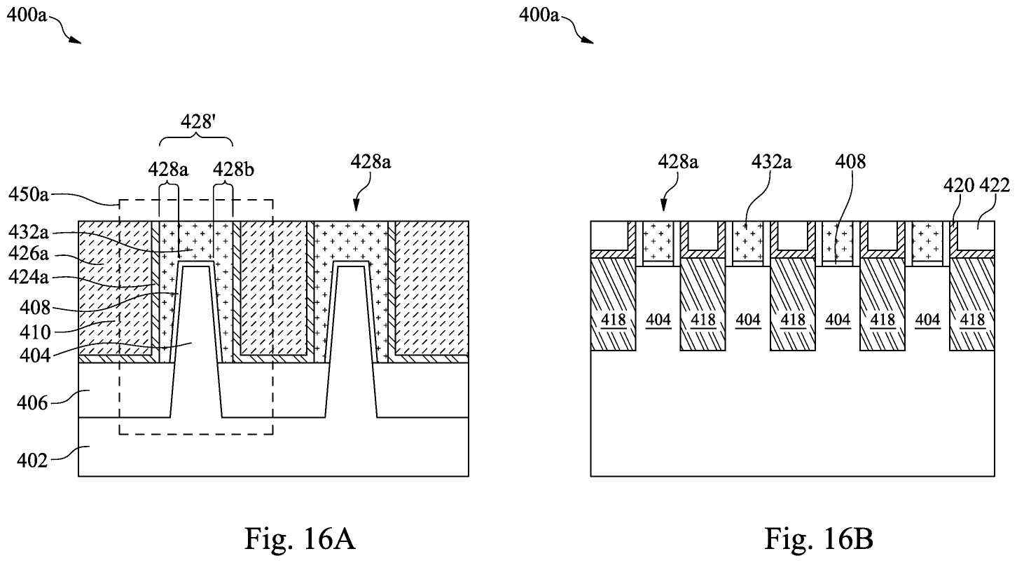

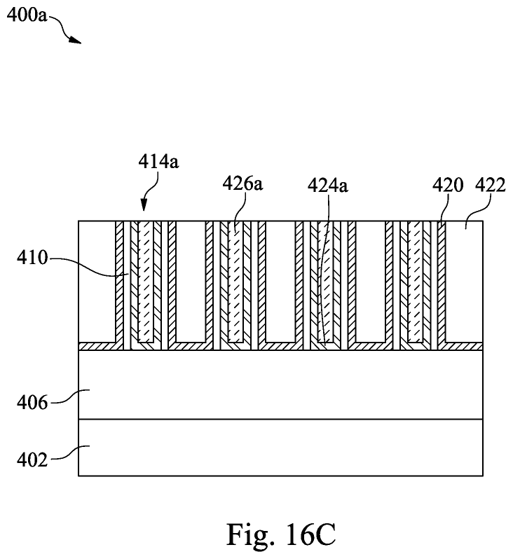

At operation 508, replacement gate structures 414a are formed as shown in FIGS. 16, 16A, 16B, and 16C. FIG. 16 is a schematic perspective view of the memory circuit 400a according to the present disclosure. FIGS. 16A, 16B, and 16C are schematic sectional view of the memory circuit 400a along lines A-A, B-B, and C-C in FIG. 16 respectively.

In some embodiments, the sacrificial gate electrode layer 410 is selectively etched to expose the sacrificial gate dielectric layer 408 below. In some embodiments, the sacrificial gate dielectric layer 408 may be removed by one or more suitable process, such as dry etch, wet etch, or a combination thereof, to expose the semiconductor fins 404. Gate cavities are formed between the sidewall spacers 412 and between the storage gate electrode layer 432a.

A gate dielectric layer 424a is then deposited on exposed surfaces in the gate cavities. Particularly, the gate dielectric layer 424a may be deposited over sidewalls of the storage gate electrode layer 432a, the sidewall spacers 412, and the isolation layer 406.

The first gate dielectric layer 424a may have different composition and dimensions for N-type devices and P-type devices and are formed separately using patterned mask layers and different deposition recipes. The gate dielectric layer 424a may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 424a may be formed by CVD, ALD or any suitable method.

The gate electrode layer 426a is then formed on the gate dielectric layer 424a to fill the gate cavities. The gate electrode layer 426a may include one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 426a may be formed by CVD, ALD, electro-plating, or other suitable method. After the formation of the gate electrode layer 426a, a planarization process, such as a CMP process, is performed to remove excess deposition of the gate electrode material and expose the top surface of the ILD layer 422.

After operation 508, a plurality of memory cells 450a are formed over the substrate 402. The memory cells 450a are similar to the two-bit memory cell 100 of FIGS. 1A-1C.

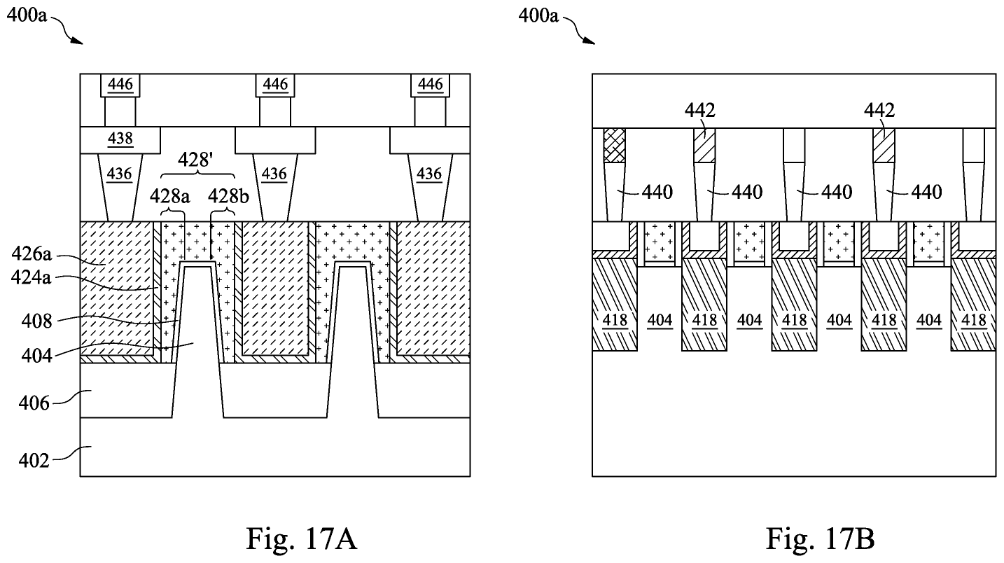

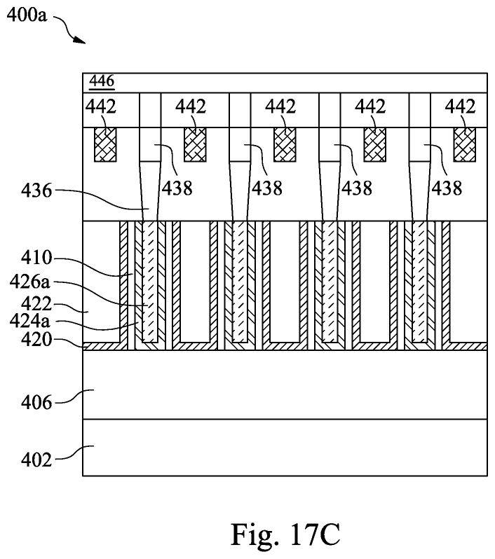

Operation 310 is then performed to form gate contact features 436 and/or source/drain contact features 440 may be formed to connect the memory cells 450a, as shown in FIGS. 17A, 17B, 17C. FIGS. 17A, 17B, and 17C are schematic sectional view of the memory circuit 400 along lines A-A, B-B, and C-C in FIG. 16 respectively.

Embodiments the present disclosure provide a MTP memory cell and methods for forming the same. The MTP memory cell includes a FinFET transistor having two or more storage modes formed around the channel region and corresponding metal gate electrodes over the storage nodes. The multi-bit memory cell may be implemented by either n-channel transistor or p-channel transistor, thus, providing design flexibility. The MTP memory cell only includes a single transistor, thus, may be used to achieve high density memory array. The MTP memory cell may be programmed/erased by various methods, including CHE, BBHH, and FN tuning, thus, provide additional design choices. Furthermore, the MTP memory cell may be fabricated using existing processing sequences, such as cut metal gate sequence.

It will be understood that not all advantages have been necessarily discussed herein, no particular advantage is required for all embodiments or examples, and other embodiments or examples may offer different advantages.

Embodiments of the present disclosure provide a memory cell, comprising a source region; a drain region; a channel region connecting the source region and the drain region, wherein the channel region has a first sidewall, a second sidewall and a top surface connecting the first sidewall and the second sidewall; a first gate dielectric layer disposed on the channel region; a storage gate electrode layer disposed on the first gate dielectric layer; a first control gate electrode layer disposed on the storage gate electrode layer, wherein the first gate control gate layer faces the first sidewall of the channel region; and a second control gate electrode layer disposed on the storage gate electrode layer, wherein the second gate control gate layer faces the second sidewall of the channel region, and the first control gate electrode layer and the second control gate electrode layer are electrically isolated from each other.

Some embodiments of the present disclosure relate to a method for operating a memory cell, comprising providing a multi-time programmable memory cell comprising: a source region; a drain region; a channel region connected between the source region and the drain region, wherein the channel region has a first sidewall, a second sidewall and a top surface connecting the first sidewall and the second sidewall; a first storage node formed on the first sidewall of the channel region; a second storage node formed on the second sidewall of the channel region; a first control gate electrode layer disposed on the first storage node; and a second control gate electrode layer disposed on the second storage node; and injecting electrons to the first storage node by applying a first control voltage on the first control gate electrode layer while applying a second control voltage to the second control gate electrode layer, wherein the first control voltage is different from the second control voltage.

Some embodiments of the present disclosure relate to an integrated circuit, comprising: an array comprising a plurality of memory cells, wherein each memory cell comprising: a source region; a drain region; a channel region connected between the source region and the drain region, wherein the channel region has a first sidewall, a second sidewall and a top surface connecting the first sidewall and the second sidewall; a first storage node formed on the first sidewall of the channel region; a second storage node formed on the second sidewall of the channel region; a first control gate electrode layer disposed on the first storage node; and a second control gate electrode layer disposed on the second storage node; a first word line connected to the first control gate electrodes layers of the memory cells in a first row in the array; a second word line connected to the second control gate electrodes layers of the memory cells in the first row in the array; a first bit line in connection with the drain regions of a first column of memory cells in the array; and a second bit line in connection with the source regions of the first column of memory cells in the array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory cell, comprising:
a source region;
a drain region;
a channel region connecting the source region and the drain region, wherein the channel region has a first sidewall, a second sidewall and a top surface connecting the first sidewall and the second sidewall;
a first gate dielectric layer disposed on the channel region;
a storage gate electrode layer disposed on the first gate dielectric layer;
a first control gate electrode layer disposed on the storage gate electrode layer, wherein the first gate control gate layer faces the first sidewall of the channel region; and
a second control gate electrode layer disposed on the storage gate electrode layer, wherein the second gate control gate layer faces the second sidewall of the channel region, and the first control gate electrode layer and the second control gate electrode layer are electrically isolated from each other.

2. The memory cell of claim 1, wherein the storage gate electrode layer comprises silicon nitride.

3. The memory cell of claim 2, wherein the storage gate electrode layer comprises:
a first portion disposed between the first control gate electrode layer and the first sidewall of the channel region;
a second portion disposed between the second control gate electrode layer and the second sidewall of the channel region; and
a top portion disposed over the top surface of the channel region, wherein the top portion connects the first portion and the second portion.

4. The memory cell of claim 2, further comprising:
a second dielectric layer disposed between the storage gate electrode layer and the first control gate electrode layer.

5. The memory cell of claim 4, wherein the first gate dielectric layer and the second dielectric layer includes different material.

6. The memory cell of claim 1, wherein the first gate dielectric layer extends along a bottom surface of the storage gate electrode layer and disposed between the storage gate electrode layer and the first control gate electrode layer.

7. The memory cell of claim 1, wherein the channel region is a p-type channel.

8. The memory cell of claim 1, wherein the channel region is a n-type channel.

9. The memory cell of claim 1, wherein the channel region comprises two or more semiconductor fins.

10. A method for operating a memory cell, comprising:
providing a multi-time programmable memory cell comprising:
a source region;
a drain region;
a channel region connected between the source region and the drain region, wherein the channel region has a first sidewall, a second sidewall and a top surface connecting the first sidewall and the second sidewall;
a first storage node formed on the first sidewall of the channel region;
a second storage node formed on the second sidewall of the channel region;
a first control gate electrode layer disposed on the first storage node; and
a second control gate electrode layer disposed on the second storage node; and
injecting electrons to the first storage node by applying a first control voltage on the first control gate electrode layer while applying a second control voltage to the second control gate electrode layer, wherein the first control voltage is different from the second control voltage.

11. The method of claim 10, wherein injecting electrons to the first storage node further comprises:
applying a source voltage on the source region; and
applying a drain voltage on the drain region, wherein the first control voltage is a positive voltage, and the second control voltage, the source voltage and drain voltage are about 0V.

12. The method of claim 10, wherein injecting electrons to the first storage node further comprises:
applying a source voltage on the source region; and
applying a drain voltage on the drain region, wherein the first control voltage is a positive voltage, the second control voltage and the source voltage are about 0V, and the drain voltage is a positive voltage.

13. The method of claim 10, further comprising:
removing electrons from the first storage node by applying a third control voltage on the first control gate electrode layer while applying a fourth control voltage to the second control gate electrode layer, wherein the third control voltage is different from the fourth control voltage.

14. The method of claim 13, wherein removing electrons from the first storage node comprising:
applying a source voltage on the source region; and
applying a drain voltage on the drain region, wherein the third control voltage is a negative voltage, and the fourth control voltage, the source voltage and drain voltage are about 0V.

15. The method of claim 13, wherein removing electrons from the first storage node comprising:
applying a source voltage on the source region; and
applying a drain voltage on the drain region, wherein the third control voltage is a positive voltage, the source voltage and drain voltage are positive voltages greater than the third control voltage, and the fourth control voltage is about 0V.

16. An integrated circuit, comprising:
an array comprising a plurality of memory cells, wherein each memory cell comprising:
a source region;
a drain region;
a channel region connected between the source region and the drain region, wherein the channel region has a first sidewall, a second sidewall and a top surface connecting the first sidewall and the second sidewall;
a first storage node formed on the first sidewall of the channel region;
a second storage node formed on the second sidewall of the channel region;
a first control gate electrode layer disposed on the first storage node; and
a second control gate electrode layer disposed on the second storage node;
a first word line connected to the first control gate electrodes layers of the memory cells in a first row in the array;
a second word line connected to the second control gate electrodes layers of the memory cells in the first row in the array;
a first bit line in connection with the drain regions of a first column of memory cells in the array; and
a second bit line in connection with the source regions of the first column of memory cells in the array.

17. The integrated circuit of claim 16, wherein the first word line and the second word line extend along a first direction, and the first bit line and the second bit line extend along a second direction.

18. The integrated circuit of claim 17, wherein the channel region extends along the first direction.

19. The integrated circuit of claim 16, wherein the memory cell further comprises:
a third storage node formed on the first sidewall of the channel region;
a fourth storage node formed on the second sidewall of the channel region, wherein the third storage node and the fourth storage node are disposed side by side with the first storage node and the second storage node respectively.
a third control gate electrode layer disposed on the third storage node; and
a fourth control gate electrode layer disposed on the fourth storage node.

20. The integrated circuit of claim 19, further comprising
a third word line connected to the third control gate electrode layers of the memory cells in the first row in the array; and
a fourth word line connected to the fourth control gate electrodes layers of the memory cells in the first row in the array.
